(19) United States
(12) Patent Application Publication
(10) Pub. No.: US 2011/0188292 A1
(43) Pub. Date: Aug. 4, 2011

(54) VARIABLE RESISTANCE MEMORY, OPERATING METHOD AND SYSTEM

(75) Inventors: Heung Jin JOO, Suwon-si (KR); Jae Hee OH, Seongnam-si (KR); Sung-Ho EUN, Seoul (KR)

(73) Assignee: SAMSUNG ELECTRONICS CO., LTD., Suwon-si (KR)

(21) Appl. No.: 12/972,945

(22) Filed: Dec. 20, 2010

(30) Foreign Application Priority Data
Jan. 29, 2010 (KR) 10-2010-0008632

(51) Int. Cl. G11C 11/00

(52) U.S. Cl. 365/148

(57) ABSTRACT

Provided is an operating method of a variable resistance memory device. The operating method applies a set pulse to a plurality of memory cells to be written in a set state, and applies a reset pulse to a plurality of memory cells to be written in a reset state. The width of the set pulse is narrower than the width of the reset pulse.

### CROSS-REFERENCE TO RELATED APPLICATIONS

This U.S. non-provisional patent application claims priority under 35 U.S.C. §119 to Korean Patent Application No. 10-2010-0008632 filed on Jan. 29, 2010, the subject matter of which is hereby incorporated by reference.

### BACKGROUND

The present disclosure relates to semiconductor memories, and more particularly, to variable resistance memories, operating methods thereof, and memory systems incorporating same.

Semiconductor memories may be variously implemented from semiconductor materials such as silicon (Si), germanium (Ge), gallium arsenide (GaAs) and indium phospide (InP). In their operative nature, semiconductor memories may be generally classified as volatile or nonvolatile.

A volatile memory loses stored data in the absence of applied power. Volatile memories include, for example, Static Random Access Memory (SRAM), Dynamic Random Access Memory (DRAM), and Synchronous Dynamic Random Access Memory (SDRAM). In contrast, a nonvolatile memories retain stored data in the absence of applied power. Nonvolatile memories include, for example, Read-Only Memory (ROM), Programmable Read Only Memory (PROM), Erasable Programmable Read Only Memory (EPROM), Electrical Erasable Programmable Read Only Memory (EEPROM)—including flash memory, and variable resistance memory devices such as Phase-change Random Access Memory (PRAM), Magnetoresistive Random Access Memory (MRAM), Resistive Random Access Memory (RRAM) and Ferroelectric Random Access Memory (FRAM).

### SUMMARY

The present disclosure provides variable resistance memories having enhanced operating speed, related operating methods, and memory systems incorporating same.

Embodiments of the inventive concept provide an operating method for a variable resistance memory device, the method comprising; applying a reset pulse to a plurality of memory cells to be written in a reset state (reset memory cells), and applying a set pulse to a plurality of memory cells to be written in a set state (set memory cells), wherein a duration of the set pulse is less than a duration of the reset pulse.

In a related aspect, applying the set pulse comprises; applying a first set pulse to the set memory cells, performing a verification operation on the set memory cells following application of the first set pulse to generate verification results, and applying a second set pulse to at least one of the set memory cells in response to the verification results.

In another related aspect, the second set pulse is equal in duration to the first set pulse.

In another related aspect, the second set pulse has a greater level than the level of the first set pulse.

In another related aspect, the at least one of the set memory cells has a reset state following application of the first set pulse as indicated by the verification results.

In another related aspect, applying the set pulse to the set memory cells comprises iteratively applying a set pulse to the set memory cells through a number of set loops until all of the set memory cells are passed by exhibiting a normal set state resistance.

In another related aspect, each set loop comprises performing a set operation using a set-loop defined set voltage, and then performing a verification operation on the set memory cells.

In another related aspect, each set-loop defined set voltage is incrementally increased with each successive set loop.

In another related aspect, each set-loop defined set voltage is incrementally decreased with each successive set loop.

In another related aspect, each successive set loop is performed during a time period less than or equal to an immediately preceding set loop.

Embodiments of the inventive concept also provide a variable resistance memory device, comprising; a memory cell array comprising a plurality of memory cells, and a read and write (R/W) circuit, wherein the R/W circuit is configured to apply a reset pulse to a plurality of memory cells to be written in a reset state (reset memory cells), and apply a set pulse to a plurality of memory cells to be written in a set state (set memory cells), wherein a duration of the set pulse is less than a duration of the reset pulse.

Embodiments of the inventive concept also provide a memory system, comprising; a variable resistance memory device, and a controller controlling the variable resistance memory device. The variable resistance memory device comprises; a memory cell array comprising a plurality of memory cells, and a read and write (R/W) circuit, wherein the R/W circuit is configured to apply a reset pulse to a plurality of memory cells to be written in a reset state (reset memory cells), and apply a set pulse to a plurality of memory cells to be written in a set state (set memory cells), wherein a duration of the set pulse is less than a duration of the reset pulse.

In a various related aspects, the variable resistance memory device and controller may be configured as a Solid State Drive (SSD), a memory card, or a smart card.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram illustrating a variable resistance memory device according to an embodiment of the inventive concept;

FIG. 2 is a block diagram further illustrating the memory cell array of FIG. 1;

FIG. 3 is a circuit diagram further illustrating an exemplary memory cell that may be incorporated within the memory cell array of FIG. 2;

FIG. 4 is a graph showing a voltage-current (V-I) characteristic for the memory cell of FIG. 3;

FIG. 5 is a graph showing the resistance of a memory cell as a function of the level of a current applied to a memory cell having a reset state;

FIG. 6 is a graph showing the resistance of a memory cell as a function of the level of a voltage applied to a memory cell having a reset state;

FIG. 7 is a graph showing effective ranges (ER) for a plurality of memory cells MC;

FIG. 8 is a graph showing write pulses according to an embodiment of the inventive concept;

FIG. 9 is a graph showing the resistance values of memory cells as a function of set pulses having different durations;

FIG. 10 is a graph showing the levels of a set pulse corresponding to memory cells having the distributed effective ranges MC1_ER to MC4_ER of FIG. 8;

FIG. 11 is a graph showing write pulses according to another embodiment of the inventive concept;

FIG. 12 is a block diagram illustrating a variable resistance memory device according to another embodiment of the inventive concept;

FIG. 13 is a graph showing the write pulses of the variable resistance memory device of FIG. 12;

FIG. 14 is a flowchart summarizing a set operation for the variable resistance memory device of FIGS. 12 and 14;

FIG. 15 is a graph showing application examples of the set pulses of the variable resistance memory device of FIG. 12;

FIG. 16 is a flowchart summarizing a set operation for the variable resistance memory device of FIG. 12 based on the set pulses of FIG. 15;

FIG. 17 is a block diagram illustrating a variable resistance memory device according to another embodiment of the inventive concept;

FIG. 18 is a flowchart summarizing the operation of the variable resistance memory device of FIG. 17;

FIG. 19 is a graph showing a written result based on set pulses and a written result based on a slow-quenching set pulse according to various embodiments of the inventive concept;

FIG. 20 is a circuit diagram illustrating another embodiment of the memory cell of FIG. 2;

FIG. 21 is a circuit diagram illustrating another embodiment of the memory cell of FIG. 2;

FIG. 22 is a block diagram of a memory system incorporating one or more variable resistance memory devices such as those described in relation to FIGS. 1, 12 and 17 according to embodiment(s) of the inventive concept;

FIG. 23 is a block diagram illustrating one possible application example for the memory system of FIG. 21; and

FIG. 24 is a block diagram of a computational system incorporating a memory system such as the one described in relation to FIG. 22.

### DETAILED DESCRIPTION OF THE EMBODIMENTS

Embodiments of the inventive concept will be described below in some additional detail with reference to the accompanying drawings. The inventive concept may, however, be embodied in different forms and should not be construed as being limited to only the illustrated embodiments. Rather, these embodiments are provided so that this disclosure will be thorough and complete, and will fully convey the scope of the inventive concept to those skilled in the art. Throughout the drawings and written description, like reference numbers and labels are used to denote like or similar elements.

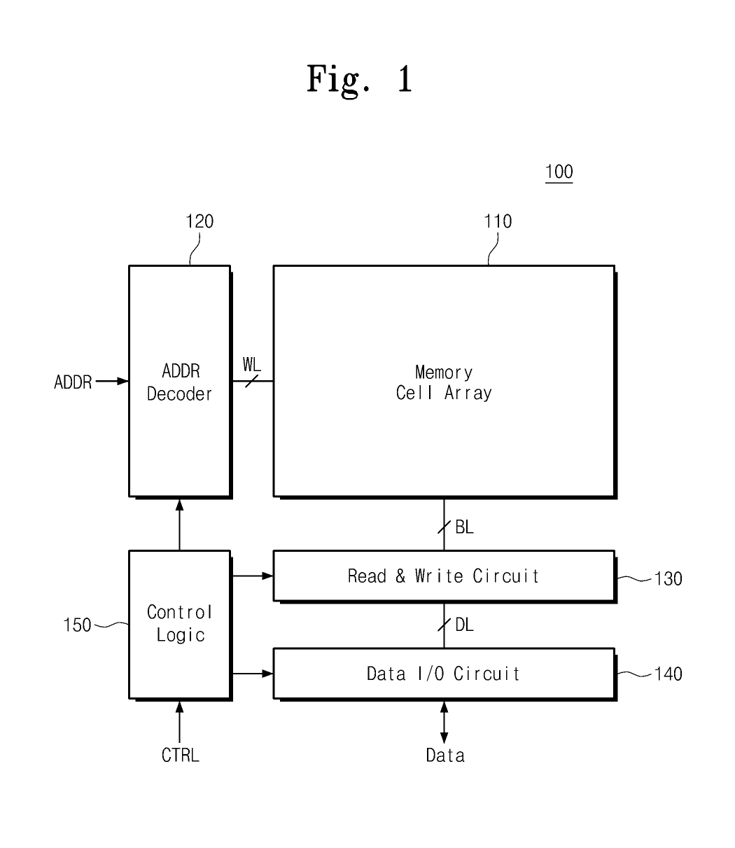

FIG. 1 is a block diagram illustrating a variable resistance memory device 100 according to an embodiment of the inventive concept.

Referring to FIG. 1, the variable resistance memory device 100 comprises a memory cell array 110, an address decoder 120, a read and write (R/W) circuit 130, a data input/output (I/O) circuit 140, and a control logic 150.

The memory cell array 110 is connected to the address decoder 120 through word lines WL, and is connected to the R/W circuit 130 through bit lines BL. The memory cell array 110 includes a plurality of memory cells. Memory cells arranged in a row direction are connected by the word lines WL. Memory cells arranged in a column direction are connected by the bit lines BL. The constituent memory cells of memory cell array 110 may be single level memory cells (SLCs) capable of storing a single bit per memory cell, and/or multi-level memory cells (MLCs) capable of storing multiple bits per memory cell.

The address decoder 120 is connected to the memory cell array 110 through the word lines WL. The address decoder 120 operates according to the control of the control logic 150. The address decoder 120 receives an externally provided address ADDR.

The address decoder 120 decodes a row address among the received address ADDR, and selects one of the word lines WL in accordance with the decoded row address. The address decoder 120 decodes a column address among the received address ADDR, and the decoded column address is transferred to the R/W circuit 130. Thus, as is conventionally understood, the address decoder 120 may include a row decoder, a column decoder, and/or one or more address buffer(s).

The R/W circuit 130 is connected to the memory cell array 110 through the bit lines BL, and is connected to the data I/O circuit 140 through data lines DL. The R/W circuit 130 operates according to the control of the control logic 150. The R/W circuit 130 receives a decoded column address from the address decoder 120. The R/W circuit 130 selects the bit lines BL with the decoded column address.

During write operations, the R/W circuit 130 receives “write data” from the data I/O circuit 140 and writes the same to the memory cell array 110. During read operations, the R/W circuit 130 receives “read data” retrieved from the memory cell array 110 and transfers the read data to the data I/O circuit 140 for subsequent provision to external circuits. In certain arrangements, the R/W circuit 130 may read data from a first region of the memory cell array 110, and write the data in a second storage region of the memory cell array 110. The R/W circuit 130 may be used to perform so-called copy-back operations. As is conventionally understood, the R/W circuit 130 may include elements such as; page buffer(s), page register(s), sense amplifier(s), write driver(s) and related column selection circuitry.

The data I/O circuit 140 is connected to the R/W circuit 130 through the data lines DL. The data I/O circuit 140 operates under the control of the control logic 150 to essentially transfer read data and/or write data (collectively or singularly, “Data” in FIG. 1) between external circuits and the R/W circuit 130. As conventionally configured, the data I/O circuit 140 includes one or more data buffer(s).

The control logic 150 is respectively connected to the address decoder 120, the R/W circuit 130 and the data I/O circuit 140 to control the overall operation of a flash memory device 100 in response to externally provided commands and/or control signal(s) CTRL.

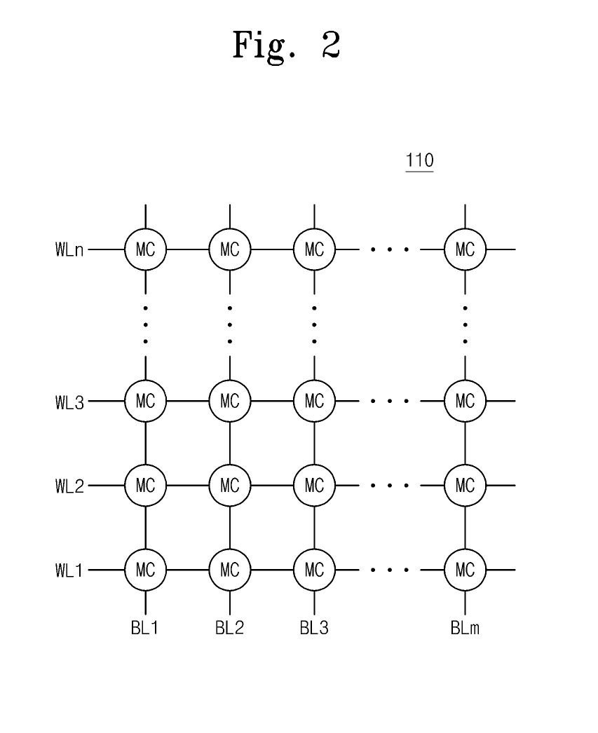

FIG. 2 is a block diagram further illustrating a relevant portion of the memory cell array 110 of FIG. 1.

Referring to FIG. 2, a plurality of memory cells MC is arranged in rows and columns. The memory cells MC are arranged along a particular row are commonly connected to one of a plurality if word lines WL1 to WLn. The memory cells MC arranged along a particular column are commonly connected (directly or indirectly) to one of a plurality of bit lines BL1 to BLm.

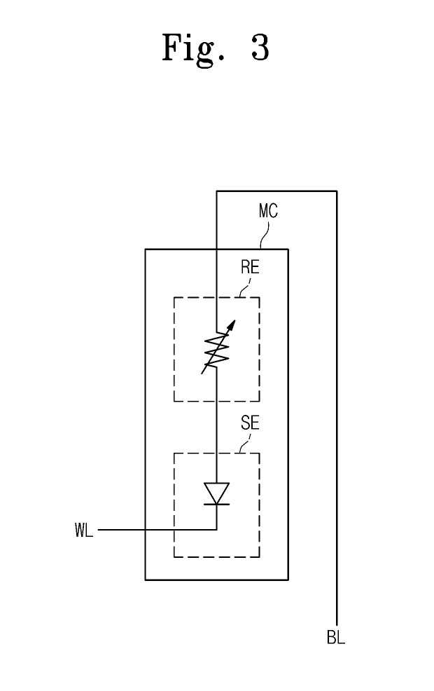

FIG. 3 is a circuit diagram illustrating one possible example of a resistive memory cell MC that may be incorporated into the memory cell array 110 of FIG. 2.

Referring to FIG. 3, the resistive memory cell MC is connected in operation between a selected word line WL and a selected bit line BL. The memory cell MC includes a selection element SE and a resistance element RE. The selection element SE opens/closes a signal path between the word line WL and the resistance element RE. When the memory cell MC is selected, the selection element SE electrically connects the corresponding word line WL and bit line BL through the resistance element RE. When the memory cell MC is non-selected, the selection element SE electrically disconnects the word line WL from the resistance element RE.

In the illustrated example of FIG. 3, the selection element SE is a diode, but a transistor (or switch) of varying type may alternately be used. When using a diode as the selection element SE, a voltage difference between the bit line BL and the word line WL may be set to a level greater than the threshold voltage of the diode in order to select the memory cell MC. If the voltage difference between the bit line BL and the word line WL is less than the threshold voltage of the diode, the memory cell MC is non-selected.

The resistance element RE may be configured from one or more variable resistance elements or materials. The constituent variable resistance elements or materials will cause the resistance element RE to exhibit different electrical resistances under different conditions (e.g., environmental, electrical, temperature, etc.). Where the resistive memory cell MC is a SLC, the resistance element RE will exhibit two different resistance states respectively associated with the binary data states of 1 and 0. Where the resistive memory cell MC is a MLC, the resistance element RE will exhibit 2^{N} resistance states respectively associated with “N” multi-bit data states.

In certain types of conventionally understood types of memory cells, the resistance elements RE will have different resistance values in accordance with different voltages or currents applied to the resistance element RE. These applied voltages or currents may result in the controlled heating and cooling of the material(s) forming the resistance element RE in order to establish corresponding material states having different resistance values. One example of such a material is chalcogenide which is commonly used to implement resistive memory cells MC of the so-called Phase Change Random Access Memory (PRAM). Thus, the resistance memory cells forming the memory cell array 110 of FIGS. 1 and 2 may be PRAM cells. However, embodiments of the inventive concept are not limited to only PRAM type device or resistive memory cells formed with a phase change material.

In the illustrated embodiments described hereafter, binary PRAM cells will be assumed as a working example of one possible type of memory cell configured in memory cell arrays. Thus, the exemplary memory cell MC will have a low resistance (or reset) state and a high resistance (or set) state.

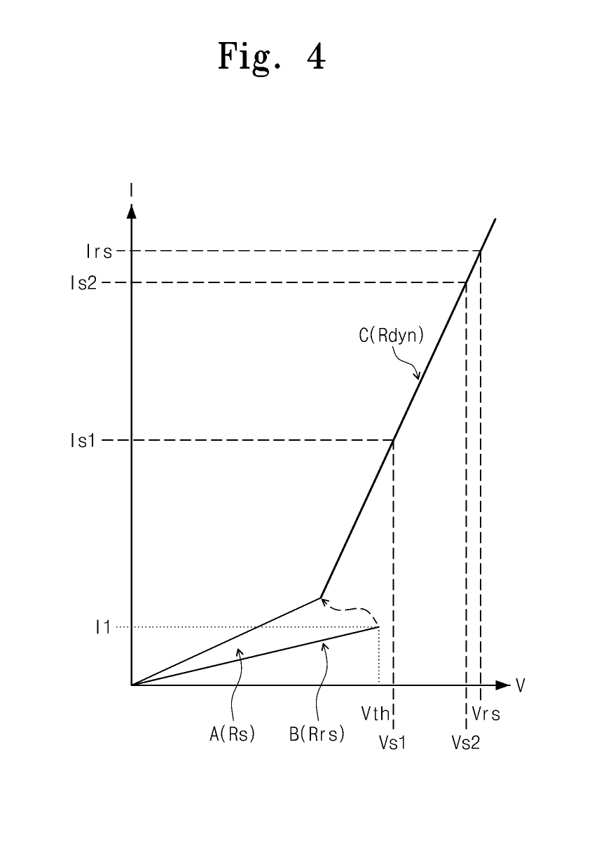

FIG. 4 is a graph showing the voltage-current (V-I) characteristic for the memory cell MC of FIG. 3 under the foregoing assumptions. In FIG. 4, the abscissa axis indicates voltage (V), and the ordinate axis indicates current (I).

Referring to FIG. 4, first to third lines A, B and C are illustrated. The first line A shows a voltage-current characteristic of a memory cell MC having a set state. The second line B shows a voltage-current characteristic of a memory cell MC having a reset state. Comparing with the first line A and the second line B, the resistance of the memory cell MC having the set state is lower than that of the memory cell MC having the reset state.

When a voltage greater than a threshold voltage Vth is applied to a memory cell MC having the reset state, the memory cell MC enters into a phase transition state. For example, when a current greater than a first current I1 is applied to the memory cell MC having the reset state, the memory cell MC enters into a phase transition state. In the phase transition state, the memory cell MC has a voltage-current characteristic based on the third line C.

When a voltage within a first set voltage Vs1 to second set voltage Vs2 range is applied to a memory cell MC, the memory cell MC is set in a set state. For example, when the voltage within the first set voltage Vs1 to second set voltage Vs2 range is applied to the memory cell MC, the memory cell MC is set in a set state having a stable set resistance Rs.

When a current within a first set current Is1 to second set current Is2 range is applied to a memory cell MC, the memory cell MC is set in a set state. For example, when the current within the first set current Is1 to second set current Is2 range is applied to the memory cell MC, the memory cell MC is set in a set state having a stable set resistance Rs.

When a voltage equal to or greater than a reset voltage Vrs is applied to a memory cell MC, the memory cell MC is set in a reset state. For example, when a current equal to or greater than a reset current Irs is applied to the memory cell MC, the memory cell MC is set in a reset state. For example, the memory cell MC having the reset state has a reset resistance Rrs.

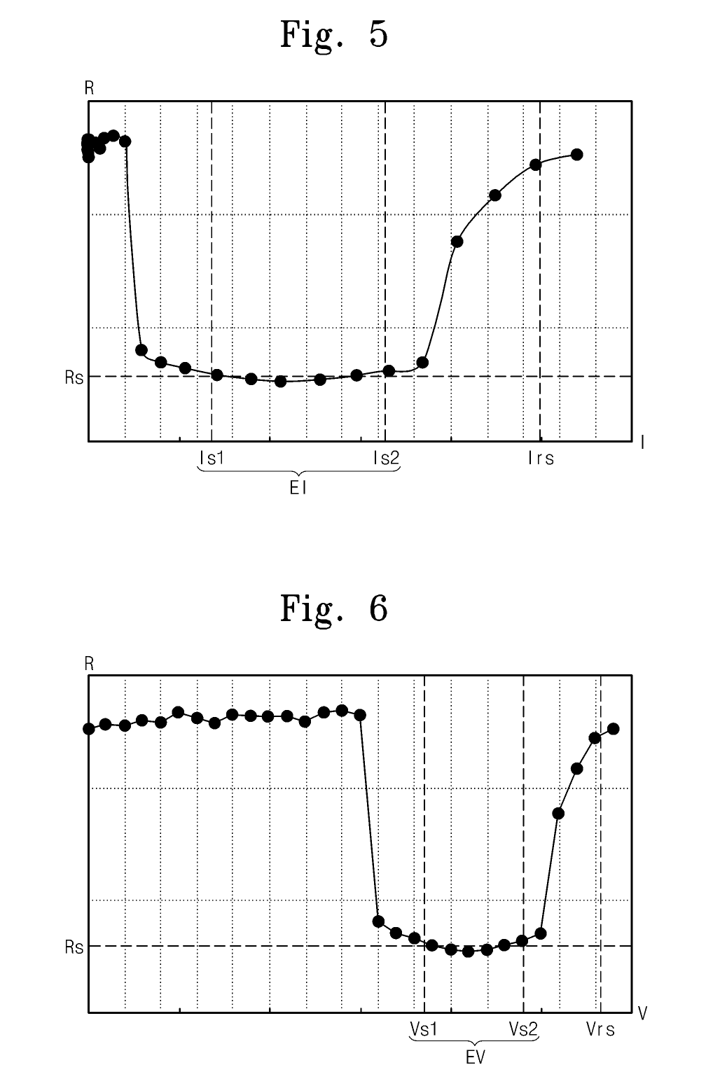

FIG. 5 is a graph showing the resistance of a memory cell MC based on the level of a current applied to a memory cell MC having a reset state. In FIG. 5, the abscissa axis indicates current (I), and the ordinate axis indicates resistance (R). The graph of FIG. 5 shows a measured result in which a current corresponding to the current value of the abscissa axis has been applied to a memory cell MC having a reset state and then the resistance value of the memory cell MC has been measured during a read operation.

Referring to FIGS. 4 and 5, when a current within a first set current Is1 to second set current Is2 range is applied to a memory cell MC, the memory cell MC has the stable set resistance Rs. For example, when a current equal to or greater than a reset current Irs is applied to the memory cell MC, the memory cell MC has a reset resistance Rrs. Hereinafter, the range Is1 to Is2 of a set current Is in which the memory cell MC has the stable set resistance Rs is called an effective current range EI.

FIG. 6 is a graph showing the resistance of a memory cell MC based on the level of a voltage which is applied to a memory cell MC having a reset state. In FIG. 6, the abscissa axis indicates voltage (V), and the ordinate axis indicates resistance (R). The graph of FIG. 6 shows a measured result in which a voltage corresponding to the voltage value of the abscissa axis has been applied to a memory cell MC having a reset state and then the resistance value of the memory cell MC has been measured during a read operation.

Referring to FIGS. 4 and 6, when a voltage within a first set voltage Vs1 to second set voltage Vs2 range is applied to a memory cell MC, the memory cell MC has the stable set resistance Rs. For example, when a voltage equal to or greater than a reset voltage Vrs is applied to the memory cell MC, the memory cell MC has a reset resistance Rrs. Hereinafter, the range Vs1 to Vs2 of a set voltage Vs in which the memory cell MC has the stable set resistance Rs is called an effective voltage range EV.

As described above with reference to FIGS. 1 through 6, the memory cell MC exhibits similar performance characteristics in response to the application of voltage or current. For example, when a current within an effective current range EI is applied to a memory cell MC, the memory cell MC is changed into a set state. When a voltage within an effective voltage range EV is applied to a memory cell MC, the memory cell MC is changed into a set state. When a current pulse or a voltage pulse having a level greater than a reset current or a reset voltage is applied, the memory cell MC is changed into a reset state.

The state of a memory cell MC is changed according to whether the level of a pulse applied to the memory cell MC is within an effective range (e.g., the effective current range EI or the effective voltage range EV) or equal to or greater than a reset level, irrespective of whether current or voltage is applied to the memory cell MC. Hereinafter, certain embodiments of the inventive concept will be described in relation to applied pulse level, regardless of any particular division between current and voltage. Those skilled in the art will thus appreciate that exemplary pulse signals are merely teaching examples that may be extended to many real world applications consistent with the scope of the inventive concept and may include applied current and/or voltage applications.

The term “effective range” denotes a range of pulse levels in response to which the state of a selected memory cell MC is changed to the reset state. Thus, an effective range ER may be an effective current range EI or an effective voltage range EV.

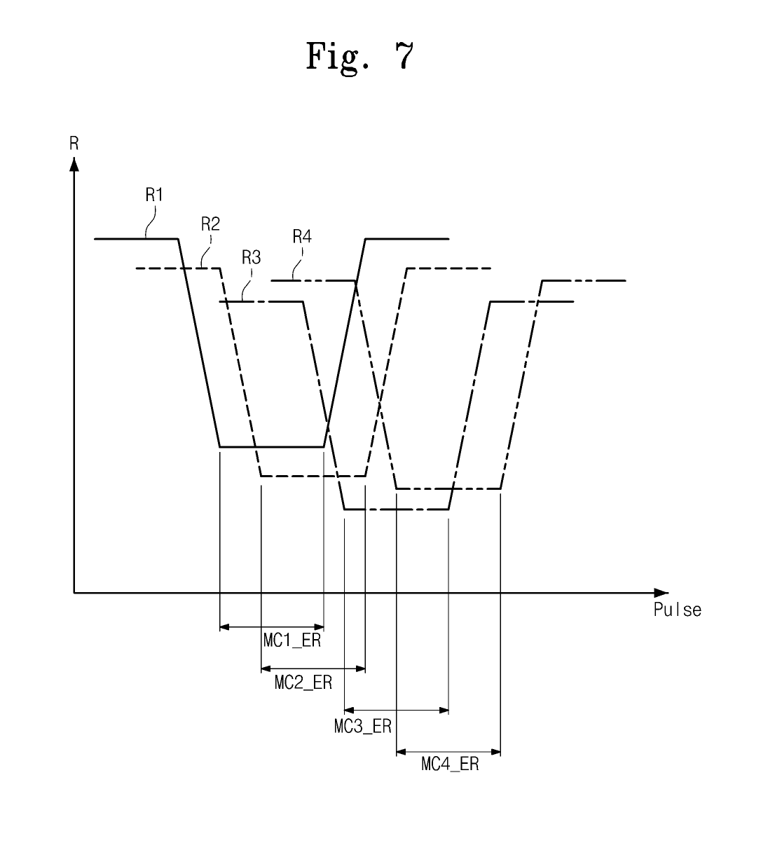

FIG. 7 is a graph showing the effective ranges ER for a plurality of memory cells MC (e.g., MC1, MC2, MC3 and MC4). In FIG. 7, the abscissa axis represents the level (or duration) of a pulse applied to the respective memory cells MC, and the ordinate axis represents the corresponding resistance value (R) of the memory cells MC.

A first resistance curve R1 shows the change of the resistance value of a first memory cell MC1 based on the level of a pulse that is applied to the first memory cell MC1. When a pulse having a level within an effective range MC1_ER is applied to the first memory cell MC1, the first memory cell MC1 is changed into a set state.

Likewise, the second to fourth resistance curves R2 to R4 show the change of the resistance values of second to fourth memory cells MC2 to MC4, respectively. The fourth memory cells MC2 to MC4 have corresponding effective ranges MC2_ER to MC4_ER, respectively.

Due to (e.g.) variations or errors arising in the fabrication processing of the memory cells, the first to fourth memory cells MC1 to MC4 may have different characteristics. For example, the effective ranges MC1_ER to MC4_ER of the first to fourth memory cells MC1 to MC4 may be distributed.

In the illustrated example of FIG. 7, the effective range MC1_ER for the first memory cell MC1 and the effective range MC2_ER for the second memory cell MC2 have significant overlapping sections. However, the effective range MC1_ER of the first memory cell MC1 does not have a significant overlapping section with the effective ranges MC3_ER and MC4_ER for the third and fourth memory cells MC3 and MC4. Likewise, the effective range MC2_ER for the second memory cell MC2 does not have a significantly overlapping section with the effective range MC4_ER for the fourth memory cell MC4.

Thus, when a set pulse having a specific level is applied to the first to fourth memory cells MC1 to MC4, at least one of the first to fourth memory cells MC1 to MC4 will probably (and erroneously) maintain a reset state. In order to prevent this errant outcome, a set pulse having a shifting level is applied to the plurality of memory cells MC in order to more reliably cause the change to the set state.

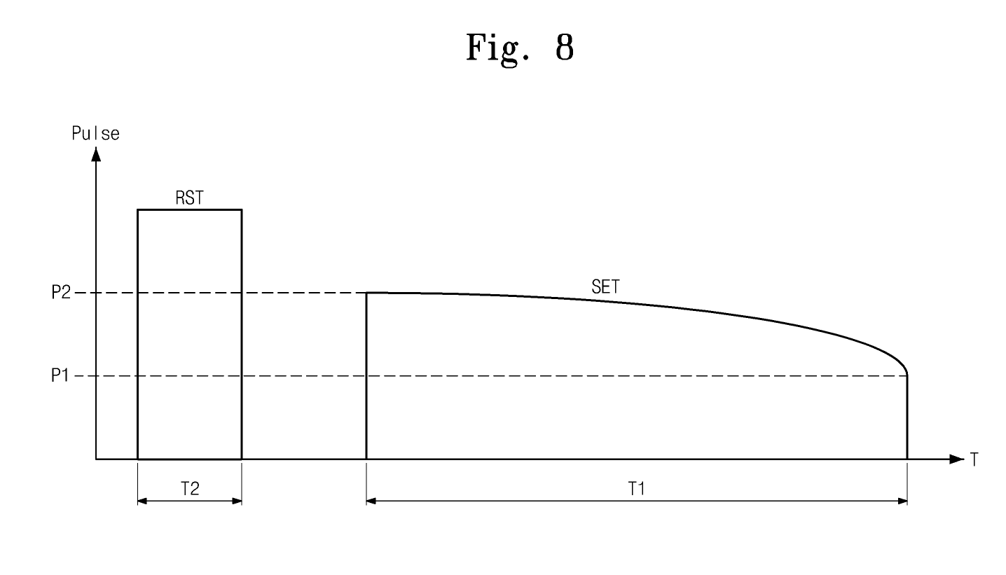

FIG. 8 is a graph of exemplary write pulses according to an embodiment of the inventive concept. In FIG. 8, the abscissa axis represents time (T), and the ordinate axis represents the level of a pulse. Consistent with the working example assumptions made above, only a reset pulse RST and a set pulse SET are illustrated. However, the teachings of the inventive concept may be readily extrapolated to resistive MLCs.

The reset pulse RST (note level above a second pulse level P2 and a reset duration of T2) is a pulse for changing memory cells MC to the reset state. The set pulse SET (note level at or below the second pulse level P2 and a set duration T1 longer than the reset duration T2) is a pulse for changing the memory cells MC to the set state.

Within this context, the level of the set pulse SET may be shifted in a level range between the second (or higher) pulse level P2 and a first (or lower) pulse level P1. In the illustrated embodiment of FIG. 8, the level of the set pulse SET is incrementally reduced in level over “a shift period” from the second pulse level P2 to the first pulse level P1.

In practical application, the “pulse shift reduction range” between the first pulse level P1 and the second pulse level P2 may be established in relation to a known (e.g., experimentally ascertained) distribution of the effective ranges ER of the memory cells MC. Accordingly, by shifting the level of the set pulse SET over a set pulse SET application period, all of the memory cells MC having different distributed effective ranges ER may be normally changed to the set state. As described above, a set pulse having a level that is incrementally reduced over a defined pulse shift reduction period (or set duration) T1 is called a slow-quenching pulse.

When the level of the set pulse SET is shifted for the duration T1 of the set pulse SET and the set pulse SET is applied to the memory cells MC, the duration T1 of the set pulse SET becomes longer than the duration T2 of the reset pulse RST. Accordingly, the writing speed of the variable resistance memory device 100 decreases due to the relatively extended duration T2 of the set pulse SET. To avoid slowing down the overall operation of a memory device incorporating resistive memory cells, certain variable resistance memory devices according to embodiments of the inventive concept apply a defined plurality of set pulses having different levels to the constituent memory cells MC.

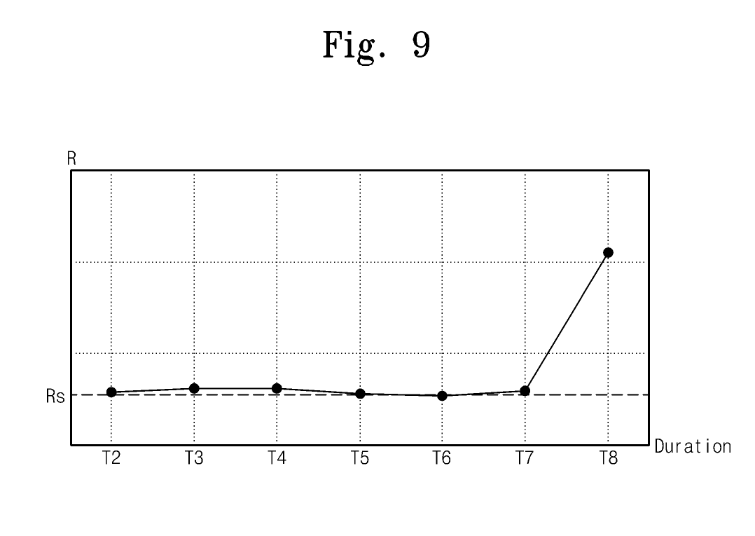

FIG. 9 is a graph showing the resistance values for memory cells MC in response to the application of set pulses SET having different durations. In FIG. 9, the abscissa axis represents the duration (application period) for a set pulse SET, and the ordinate axis represents the resistance value (R) for the memory cell MC. Exemplarily, FIG. 9 shows a measured result (resistance value) in which set pulses have been applied to the specific memory cell of a Test Element Group (TEG). For example, set pulses applied to a specific memory cell MC have a specific level within the effective range ER of the specific memory cell MC. The respective duration of the set pulses applied to the specific memory cell MC decrease along the abscissa-axis direction.

Referring to FIG. 9, when set pulses having the second to seventh durations (T2 to T7) are applied, the specific memory cell MC has a normal set state. In one example, the second duration T2 corresponds to the reset pulse duration described above in relation to FIG. 8. The third to seventh durations (T3 to T7) are durations less than the second duration T2. In one more specific example, the second time T2 is about 90 ns, and the third to seventh durations (T3 to T7) are about 70 ns, 50 ns, 40 ns, 30 ns and 20 ns, respectively.

When a set pulse having the eighth duration (T8) is applied, the specific memory cell MC does not normally change to the set state. In the specific example illustrated in FIG. 9, the eighth time (T8) is about 10 ns.

Thus, as shown in FIG. 9, when the duration of the set pulse is greater than or equal to a predetermined value (e.g., about 20 ns or the seventh duration T7 less than the reset duration), a memory cell MC will be normally changed to (or be written in) the set state. That is, based on a set pulse SET having the duration T7 (e.g., about 20 ns) which is less than the duration T2 (e.g., about 90 ns) for the reset pulse RST, a memory cell MC may be written in a set state.

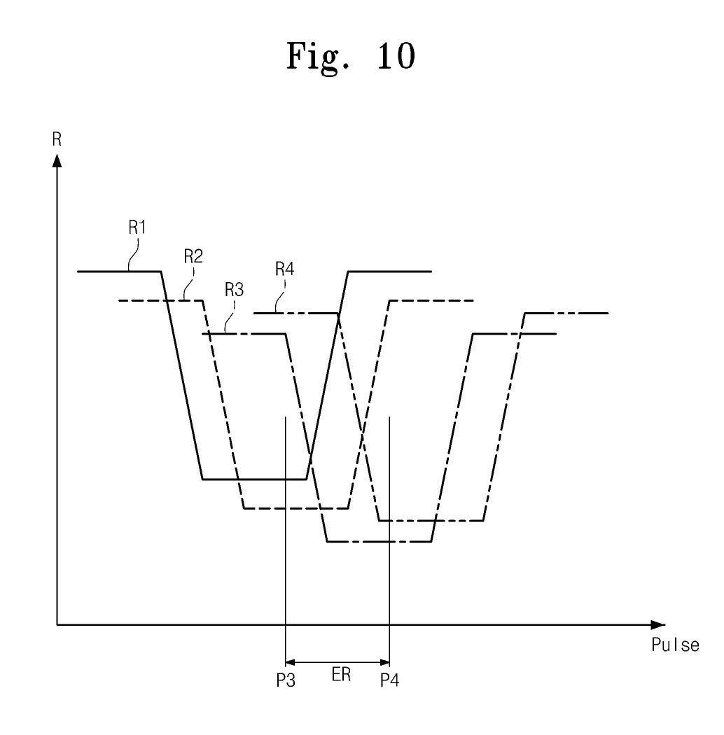

FIG. 10 is a graph showing the levels of a set pulse which corresponds to exemplary memory cells MC1 to MC4 having the distributed effective ranges MC1_ER to MC4_ER like FIG. 7.

Referring to FIG. 10, when a set pulse SET having a third level P3 is applied for the seventh duration T7 (e.g., about 20 ns), the first and second memory cells MC1 and MC2 will be written in the set state. When a set pulse SET having a fourth level P4 is applied for the seventh duration T7, the third and fourth memory cells MC3 and MC4 will be written in the set state.

That is, when pulses having a duration less than the reset pulse RST and also having different levels are applied to the memory cells MC1 to MC4, all of the memory cells MC1 to MC4 may be normally written in the set state.

Of note, the particular level of the third level P3 and fourth level P4 may be established in view of the known effective ranges ER for the memory cells MC1 to MC4. For example, the difference between the third level P3 and the fourth level P4 may be set so as to correspond with the difference in effective ranges ER for the memory cells MC1 to MC4. That is, the difference between the third level P3 and the fourth level P4 may be set so as to correspond with an average value of the effective ranges MC1_ER to MC4_ER of the memory cells MC1 to MC4. Alternately, the difference between the third level P3 and the fourth level P4 may be set as a minimum value between the effective ranges MC1_ER to MC4_ER of the memory cells MC1 to MC4. When the increment of the set pulse SET is set according to the effective ranges ER of the memory cells MC1 to MC4, the number of times that the set pulse SET must be applied to ensure proper change to the set state may be minimized.

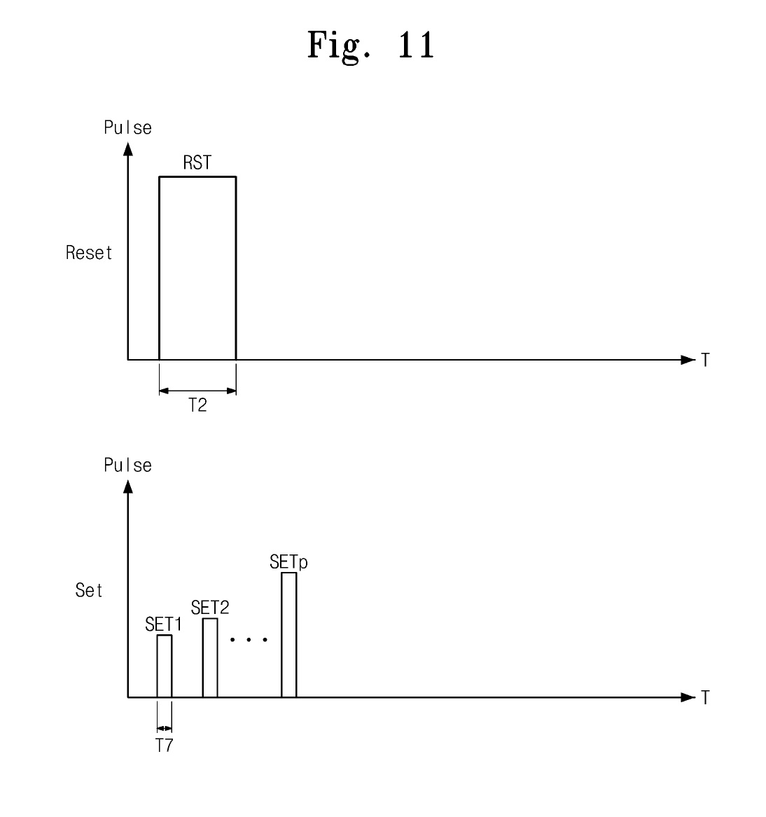

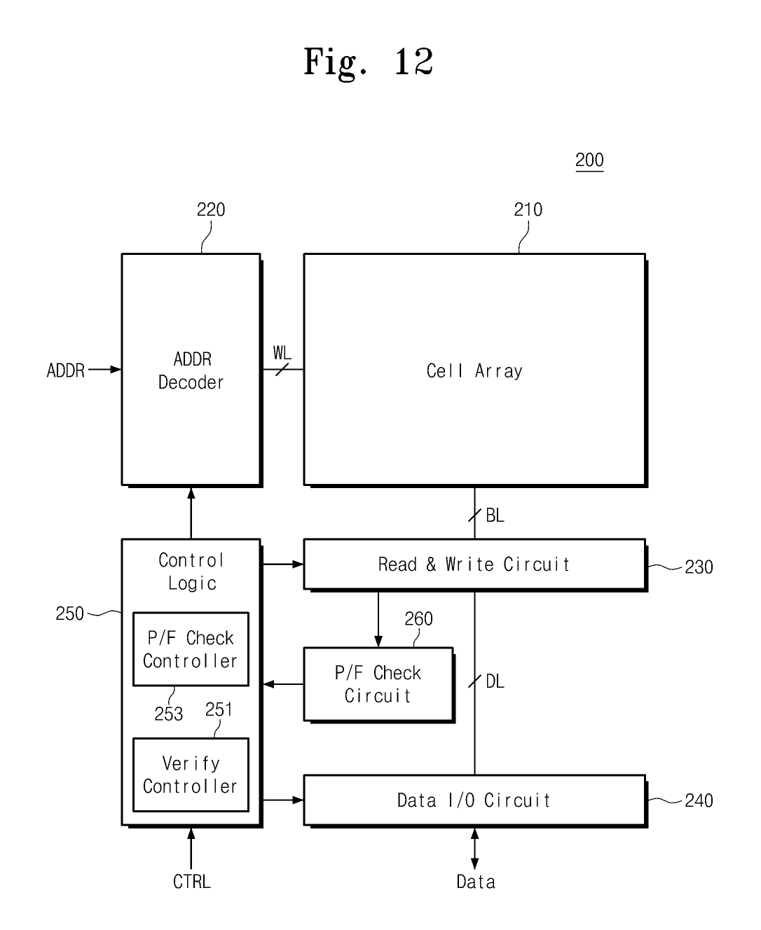

FIG. 11 is a graph showing write pulses according to another embodiment of the inventive concept. In FIG. 11, the abscissa axis represents time (T), and the ordinate axis represents the level of a pulse.

Referring to FIG. 11, a reset pulse RST is assumed to have a reset duration (e.g., T2). During a write operation, the reset pulse RST having the reset duration T2 is applied to memory cells MC such that the memory cells MC are written in the reset state.

Moreover, a plurality of set pulses SET1 to SETp, each having a duration T7 less than the reset duration T2 of the reset pulse RST, are shown in FIG. 11. The plurality of set pulses SET1 to SETp have sequentially incremented levels. During a write operation, the plurality of set pulses SET1 to SETp are respectively applied to memory cells MC such that the memory cells MC are written in the set state. The step increment between successive set pulses SET1 to SETp may be defined in view of the known effective ranges ER for the memory cells MC.

As described above with reference to FIGS. 9 and 10, the duration of each set pulse may be less than the reset duration for the reset pulse RST. In one more particular embodiment, the duration of a set pulse SET may be equal to about one-fifth the reset duration for the reset pulse RST. Accordingly, as the number of applied set pulses SET1 to SETp and their duration are adjusted, the time required to perform memory cell set operations may be decreased. As a result, the overall operating speed of the variable resistance memory device 100 may be increased.

FIG. 12 is a block diagram of a variable resistance memory device 200 according to another embodiment of the inventive concept.

Referring to FIG. 12, a variable resistance memory device 200 comprises a memory cell array 210, an address decoder 220, a read and write (R/W) circuit 230, a data input/output (I/O) circuit 240, a control logic 250, and a pass/fail (P/F) check circuit 260.

The memory cell array 210, the address decoder 220 and the data I/O circuit 240 may be similarly configured with the memory cell array 110, the address decoder 120 and the data I/O circuit 140 as described above with reference to FIG. 1.

Comparing the R/W circuit 130 of FIG. 1, the R/W circuit 230 additionally performs a verification operation. For example, the R/W circuit 230 applies a set pulse to memory cells MC to be written in set states and then applies a verification pulse. In certain embodiments of the inventive concept, the verification operation may be performed similar to a read operation. The verification operation essentially includes making a determination regarding the resistance state(s) of the memory cells MC. The result of the verification operation is provided to the P/F check circuit 260.

The P/F check circuit 260 receives the verification operation results from the R/W circuit 230. The P/F check circuit 260 determines whether the memory cells MC to be written in the set states have “normal” set resistances Rs. This pass/fail determination result is then provided to the control logic 250.

The control logic 250 controls the R/W circuit 230 so as to perform the verification operation. The control logic 250 receives the result of the pass/fail determination from the P/F check circuit 260. Based on the received pass/fail determination result, the control logic 250 controls execution of the write operation.

For example, when all the memory cells MC to be written in the set states are normally written in the set states, the control logic 250 terminates the ongoing set operation. However, if one or more of the memory cells MC to be written in the set state errantly maintain a reset state, the control logic 250 causes the R/W circuit 230 to continue the iterative application of the set operation after properly defining the set pulse(s) being applied.

Hence, the control logic 250 may include a verification controller 251 and a P/F check controller 253. The verification controller 251 controls the R/W circuit 230 during the verification operation, and the P/F check controller 253 controls the P/F check circuit 260 during the P/F determination operation. In this manner, iteratively applied write operation may be effectively controlled by the P/F check controller 253.

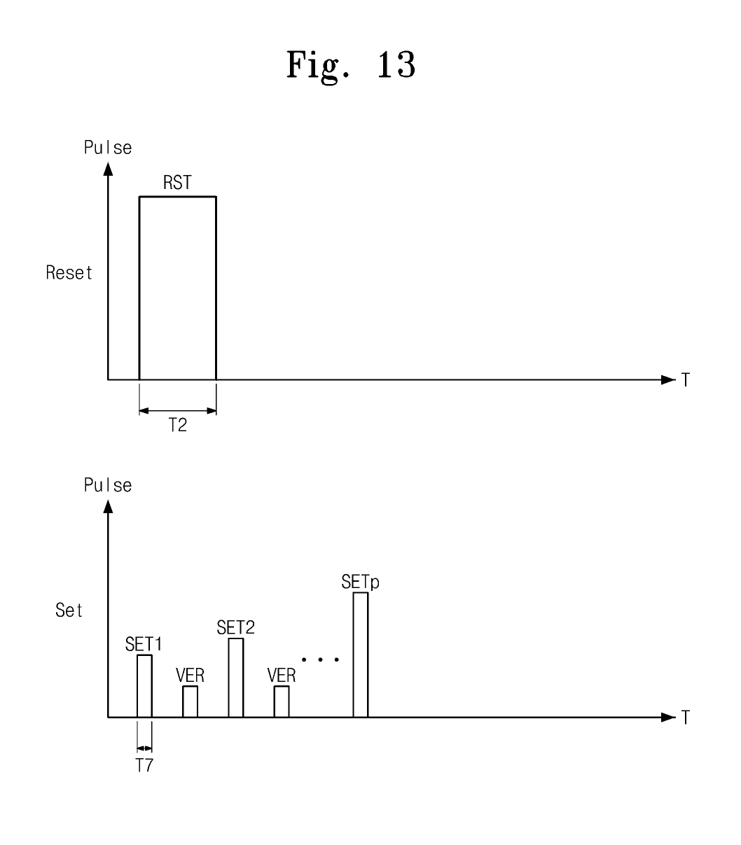

FIG. 13 is a graph further illustrating a plurality of write pulses applied during a write operation being executed by the variable resistance memory device 200 of FIG. 12. In FIG. 13, the abscissa axis represents time (T) and the ordinate axis represents the level of a pulse.

As before, the reset pulse RST is applied during a reset operation, wherein the reset pulse RST has the reset duration (e.g., T2).

Then, during a set operation, set pulses SET1 to SETp are applied. First, a first set pulse SET1 is applied to memory cells MC to be written in set states. Subsequently, a verification pulse VER is applied to the memory cells MC to which the first set pulse SET1 is applied. That is, the verification operation is performed, wherein the verification operation includes an operation (e.g., similar to a read operation) for determining the resistance value of the memory cells MC.

An operation, in which one set pulse SET1 and one verification pulse VER are applied to the memory cells MC, forms one set operation iteration (or “set loop”). As the set loop is repeated throughout the set operation, the level of the set pulse SET may be increased sequentially.

As illustrated in FIG. 13, the duration of the verification pulse VER may be the same as the duration (e.g., T7) of the set pulse SET, but in other embodiments it may be different. For example, the duration of the verification pulse VER may be less than (or greater than) the set duration for the set pulse SET.

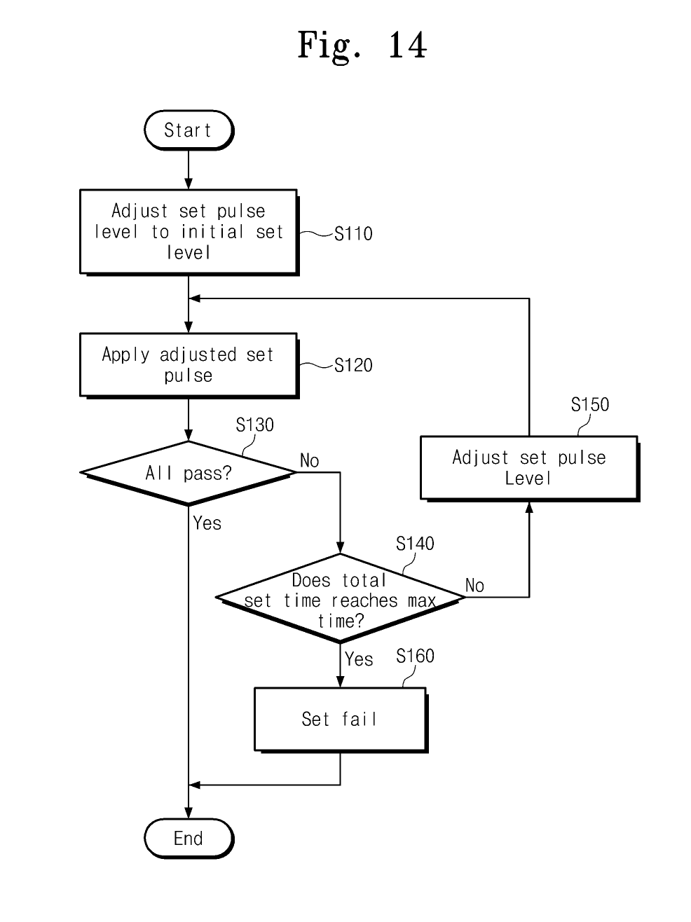

FIG. 14 is a flowchart summarizing one possible set operation for the variable resistance memory device 200 of FIG. 12.

Referring to FIGS. 12 and 14, the level of the set pulse SET is adjusted to an initial set level (S110). Per FIG. 13, the initial set level for the set pulse may be a first set pulse SET1. Then the adjusted set pulse (here, the first set pulse SET1) is applied to selected memory cells MC to be written in the set state (S120).

The variable resistance memory device 200 determines whether all the memory cells MC are “passed” (i.e., are correctly written and exhibit normal set resistances Rs) (S130). For example, a verification pulse may be applied to the memory cells MC to which the first set pulse SET1 has been applied. Based on the verification results, the variable resistance memory device 200 may terminate (END) the set operation if all of the memory cells MC are passed (S130=YES).

However, if one or more memory cells MC is failed (S130=NO), the set operation continues with a determination as to whether a currently cumulative set time has exceeded a maximum allowable set time (S140). Of note, an “all pass” determination (S130) may be made in relation to a number of acceptable errors or correctable errors consistent with an error detection/correction (ECC) capability (not illustrated but conventionally understood) for the variable resistance memory device 200.

If the maximum allowable set time has been exceeded (S140+YES), the set operation terminates (END) after generating a set fail (or bad cell) indication for one or more of the memory cells MC (S160). However, if the maximum allowable set time has not been exceeded (S140=NO), the level (and/or duration) of the set pulse is adjusted (re-defined) (S150) and the set operation begins a next set loop (i.e., return to step S120). Thus, until each one of the memory cells MC receiving the set operation is either passed or failed, set loop iterations are continued with the commensurate adjustments and applications of the set pulse SET.

Whenever the level of the set pulse SET is adjusted, different memory cells MC are written in the set states. Accordingly, when performing the set operation while adjusting the level of the set pulse SET, the memory cells MC may be written in the set states. Moreover, based on the verification operation, the set operation is ended when the memory cells MC are written in the set states. Accordingly, an operation is prevented which applies undesired set pulses SET to the memory cells MC. Therefore, the operating speed of the variable resistance memory device 200 may be increased.

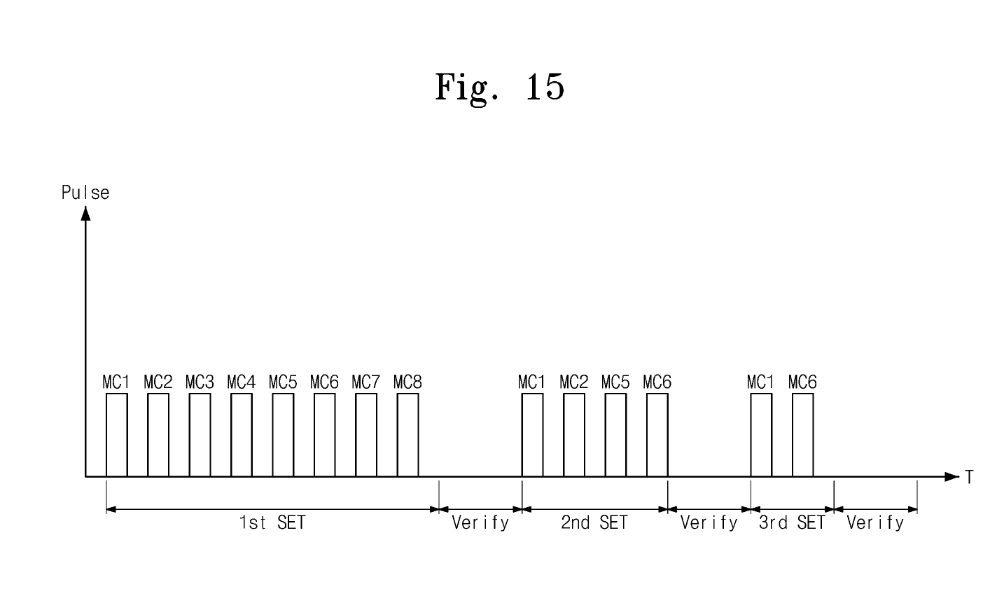

FIG. 15 is a graph further illustrating one possible application example for incrementally applied set pulses within the variable resistance memory device 200 of FIG. 12. In FIG. 15, the abscissa represents time (T) and the ordinate axis represents the level of a pulse.

The exemplary set pulse SET may be conventionally generated by a charge pump. The capacity of the charge pump may be determined in consideration of the area and power consumption of the variable resistance memory device 200. The number of memory cells MC that may apply set pulses SET at one time may be determined according to the capacity of the charge pump. In the illustrated example of FIG. 15, it is assumed that a set pulse SET may be applied to only a single memory cell MC at any given time. However, those skilled in art will recognize that the set pulse SET may be applied to two or more memory cells MC at once.

In the illustrated example, it is further assumed that the write operation is performed on a word or sector basis defined by a corresponding word unit or sector unit (e.g., an 8-bit word unit). As before, binary memory cells MC are assumed.

Thus, in FIG. 15 eight (8) memory cells MC1 to MC8 are written in the set state. Consistent with the example of FIG. 14, the first set pulse SET1 is initially applied to each one of the eight (8) memory cells MC1 to MC8, and may be applied to each one of the eight (8) memory cells MC1 to MC8 up to eight times.

Subsequently, the verification operation is performed using (e.g.,) a power source voltage (Vcc). That is, the verification pulse VER need not be generated by a separate charge pump, and the verification pulse VER may be applied to all eight (8) memory cells MC at the same time. Alternately, the verification pulse VER may be applied to a sub-set of (e.g.,) four (4) memory cells MC1 to MC4 or MC5 to MC8 at the same time. In FIG. 15, the corresponding verification pulses applied during each verification period (Verify) are omitted for the sake of clarity.

In the illustrated example of FIG. 15, it is assumed that the third, fourth, seventh and eighth memory cells MC3, MC4, MC7 and MC8 are passed by a first set loop. Thus, for the second set loop the passed memory cells MC3, MC4, MC7 and MC8 are write operation inhibited (i.e., the second and successive set pulses SET2 . . . SETp are not applied to the passed memory cells).

During a second set loop (2nd SET), properly adjusted second set pulses SET2 are applied to only failed memory cells MC1, MC2, MC5 and MC6. That is, the second set pulse SET2 is applied a total of four (4) times. Thus, the second set loop is markedly shorter in duration that the first set loop (1^{st} SET).

During the second set loop, it is assumed that the second and fifth memory cells MC2 and MC5 are passed. Thus, during a third set loop (3rd SET), the again adjusted set pulses SET3 are applied to only memory cells MC1 and MC6. Again, each successive set loop may be shorter in duration since passed memory cell MC are not included.

Once all memory cells are passed, the set operation is terminated as no more set loops need to be performed. Since the number of times the set pulse SET may be applied in progressive decreases per succeeding set loops, the write operation speed for the variable resistance memory device 200 may be increased. Moreover, the power consumption by the charge pump generating the set pulses SET1 to SETp may be reduced accordingly.

In the illustrated example of FIG. 15, the respective levels for the set pulses SET applied during the respective set loops are shown with a constant (or non-incremented) value. But as previously described with reference to FIGS. 11 through 14, the level for the set pulses may be sequentially adjusted per each set loop.

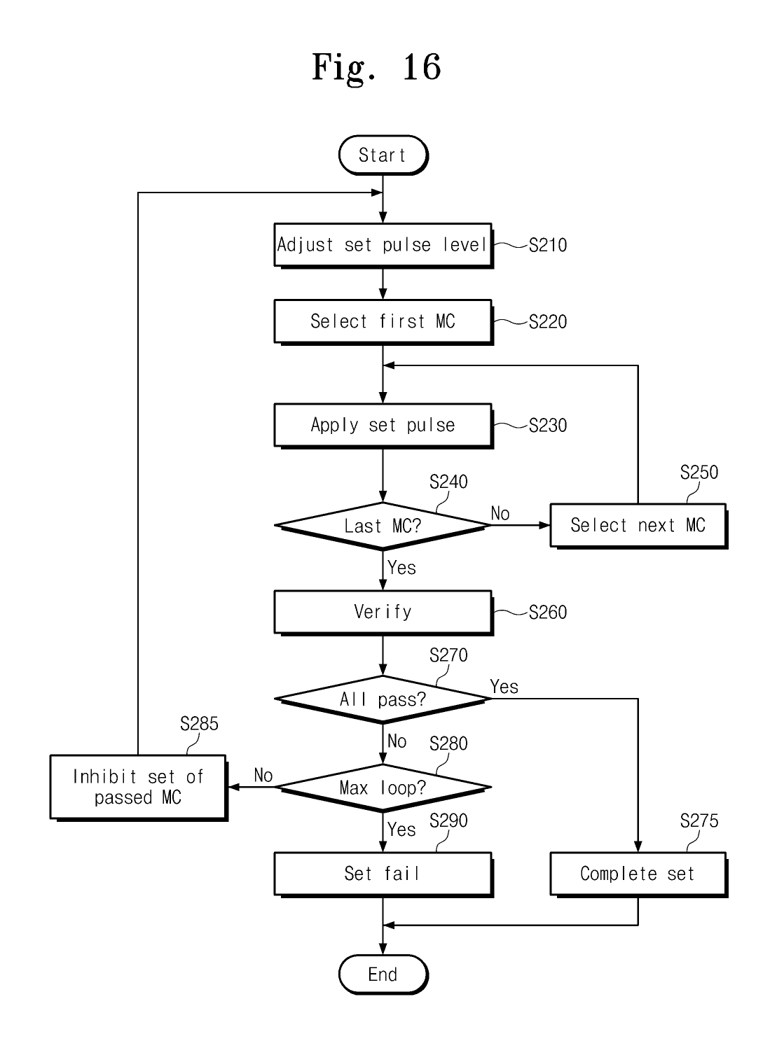

FIG. 16 is a flowchart summarizing another possible set operation for the variable resistance memory device 200 of FIG. 12 assuming the application of the constant level set pulses of FIG. 15.

Referring to FIGS. 12, 15 and 16, the level of the set pulse SET is adjusted to the defined constant level (S210). The first memory cell MC is selected from among the memory cells MC to be written in the set states (S220). When the variable resistance memory device 200 is configured to simultaneously apply the set pulse SET to one memory cell MC, only one memory cell MC is selected. However, when the variable resistance memory device 200 is configured to simultaneously apply the set pulse SET to a plurality of memory cells MC, a plurality of memory cells MC are selected.

The adjusted set pulse SET is applied to the selected memory cell MC (S230), and then the variable resistance memory device 200 determines whether the selected memory cell MC is the last memory cell MC in a defined word unit or sector unit (S240). When the selected memory cell MC is not the last memory cell MC (S240+NO), a next memory cell MC is selected (S250) and the current set loop continue (S230 and S240).

However, when the selected memory cell MC is the last memory cell MC, (S240=YES), a verification operation is performed (S260) for the current set loop. The verification operation of FIG. 16 may be similar to that described in relation to FIG. 15.

The verification results obtained from the verification operation (S260) may be used to determine whether all the memory cells MC are passed (S270). When all the memory cells MC are passed (S270=YES), the set operation is terminated for the memory cell set (e.g., the word unit or sector unit) (S275). When all the memory cells MC are not passed (S270=NO), a max set loop determination is made (S280). Where one or more memory cells MC remain not properly written in the set state (e.g., per a number of correctable bits), the set operation is terminated with one or more set fail indications (S290). Otherwise, passed memory cells are inhibited (S285) and the set operation continues to a next set loop.

In the above-described embodiment, determining whether a number of set-loop times has reached a maximum number of loops has been described (e.g., S280). However, as suggested above with reference to FIG. 13, this particular approach (maximum loop iterations) may be replaced by a maximum operating time determination.

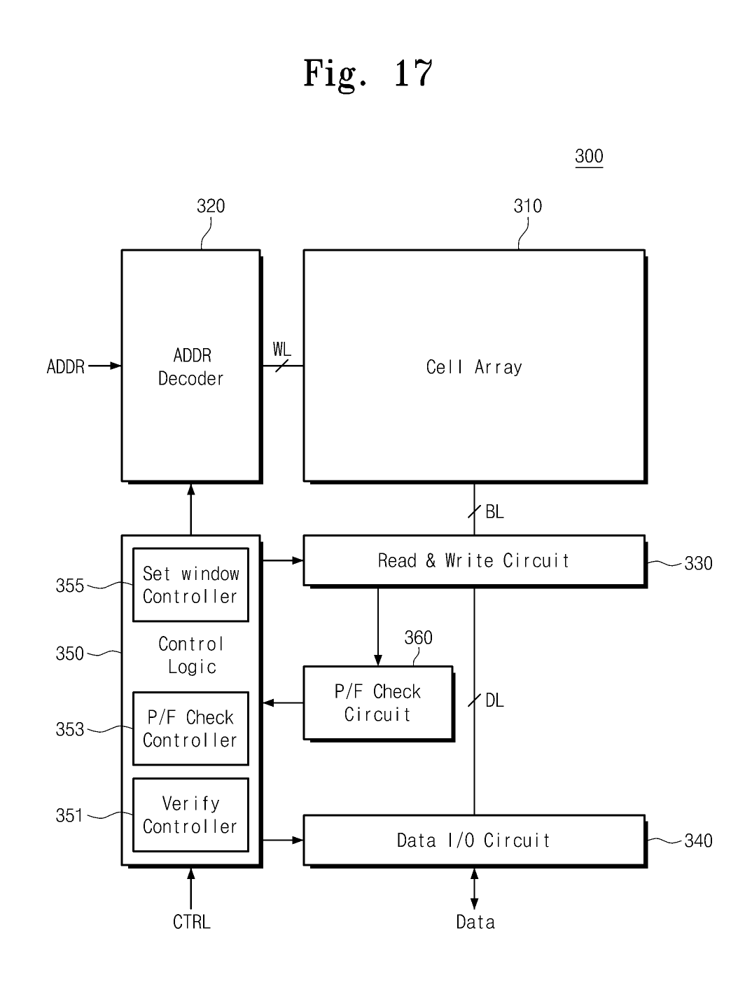

FIG. 17 is a block diagram of a variable resistance memory device 300 according to another embodiment of the inventive concept.

Referring to FIG. 17, a variable resistance memory device 300 comprises a memory cell array 310, an address decoder 320, a read and write circuit 330, a data I/O circuit 340, a control logic 350, and a P/F check circuit 360.

The memory cell array 310, the address decoder 320, the read and write circuit 330, the data I/O circuit 340 and the P/F check circuit 360 may be similarly configured to that of the memory cell array 210, the address decoder 220, the R/W circuit 230, the data I/O circuit 240 and the P/F check circuit 260 of FIG. 12,

However, comparing the control logic 250 of FIG. 12, the control logic 350 of FIG. 17 further comprises a set window controller 355. The set window controller 350 controls a window to which set pulses SET may be applied. For example, the set window controller 355 may control an incremental step-increase for the sequence of applied set pulses SETT to SETp.

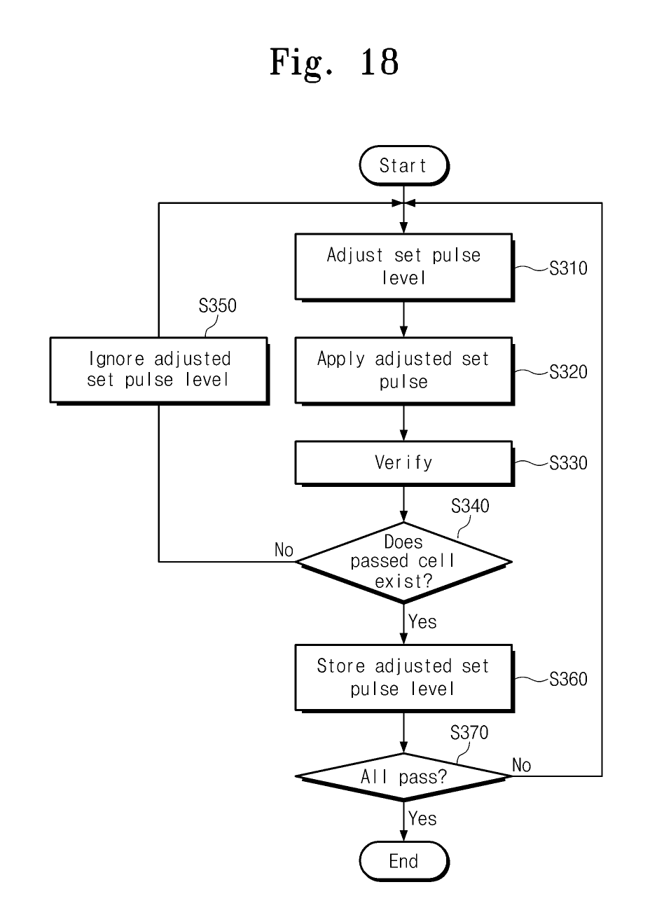

FIG. 18 is a flowchart summarizing one possible set operation for the variable resistance memory device 300 of FIG. 17.

Referring to FIGS. 17 and 18, the level of the set pulse SET is adjusted (S310) like operation 5210 of FIG. 16. The adjusted set pulse SET is then applied (S320).

A verification operation is then applied to the memory cells MC (S330). Based on the verification operation results, the variable resistance memory device 300 determines whether the memory cells MC are passed (S340). When memory cells MC that are passed by the adjusted set pulse SET do not exist, the level of the adjusted set pulse SET is ignored (S350). When memory cells MC that are passed by the adjusted set pulse SET exist, the level of the adjusted set pulse SET is stored (S360).

The variable resistance memory device 300 determines whether all the memory cells MC are passed (S370). For example, the variable resistance memory device 300 determines whether cells equal to or less than a predetermined number among the memory cells MC are failed. When the memory cells MC are passed, a set operation is terminated. When failed memory cells exist in the memory cells MC, the level of the set pulse SET is again adjusted (S310). Subsequently, another set loop (S320 through 5370) is performed.

The operations 5310 through 5370 may be performed under the control of the set window controller 355. That is, the set window controller 355 may be used to detect and store the level of the set pulse SET for changing the memory cells MC to the set state. Subsequently, the level of the set pulse SET may be adjusted on the basis of level information stored by the set window controller 355.

In possible approach, operations 5310 to 5370 may be performed on a test device, and the resulting detected levels for the set pulse SET may be stored in the set window controller 355. Subsequently, the level of the set pulse SET is adjusted on the basis of level information stored by the set window controller 355.

Since only necessary and effective set pulses SET for writing the memory cells MC in the set state are used during the write operation, the operating speed of the variable resistance memory device 300 may be increased accordingly.

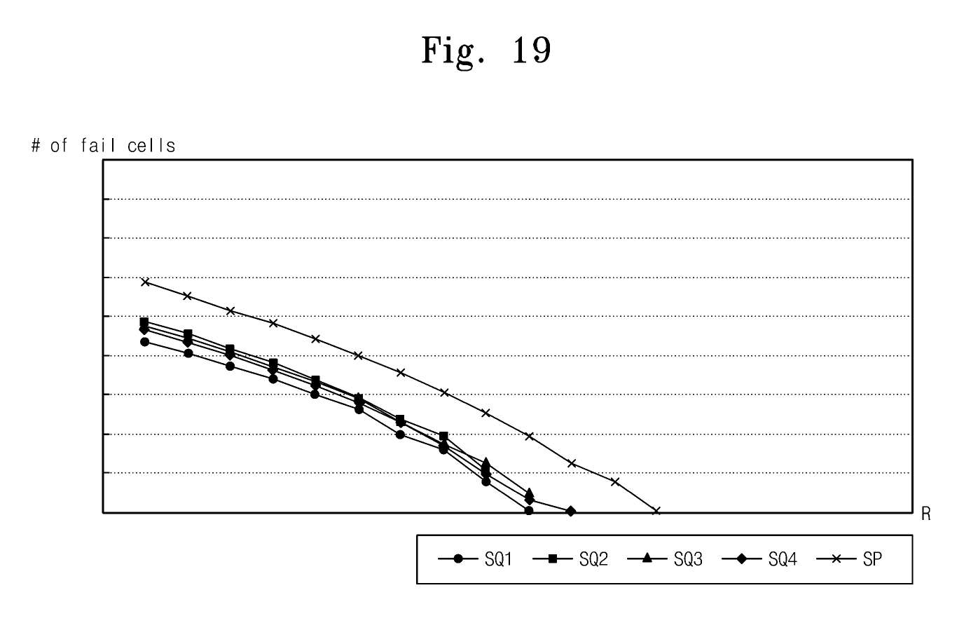

FIG. 19 is a graph showing write operation results based on application of set pulses SET according to an embodiment of the inventive concept in relation to write operation result based on a slow-quenching set pulse. In FIG. 19, the abscissa axis indicates the resistance (R) of memory cells, and the ordinate axis indicates a number of fail cells. Of note, as advance is made along the abscissa-axis direction, the resistance of the memory cells MC decreases. That is, the plot curves shown in FIG. 19 show a distribution of fail cells having resistances greater than a normal set resistance Rs.

A first slow-quenching curve SQ1 shows the number of fail cells when the duration of the set pulse SET is set to about 1030 ns. A second slow-quenching curve SQ2 shows the number of fail cells when the duration of the set pulse SET is set to about 515 ns. A third slow-quenching curve SQ3 shows the number of fail cells when the duration of the set pulse SET is set to about 577 ns. A fourth slow-quenching curve SQ4 shows the number of fail cells when the duration of the set pulse SET is set to about 640 ns. Furthermore, a step pulse curve SP varies the level of the set pulse SET according to an embodiment of the inventive concept and shows the number of fail cells when application is made.

The step pulse curve SP shows the number of fail cells when only set pulses are applied without separate verification. Although a verification operation is not performed, the number of fail cells by the set pulse according to an embodiment of the inventive concept is shown similarly to the number of fail cells by the slow-quenching set pulse. Accordingly, when the verification operation is additionally performed and a set pulse window is controlled, the number of fail cells can be more reduced.

In the above-described embodiments, it has been shown that the level of the set pulse SET sequentially increases or not as the set loop is repeated.

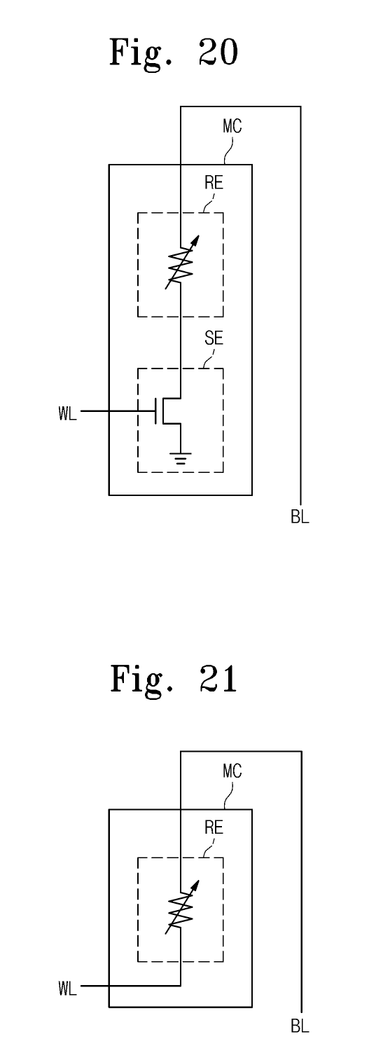

FIG. 20 is a circuit diagram illustrating another possible embodiment for the memory cell MC of FIG. 2.

A memory cell includes a resistance element RE and a selection element SE. Comparing with the memory cell MC that has been described above with reference to FIG. 3, the selection element SE of the memory cell MC includes a transistor. Furthermore, the selection element SE connects a bit line BL and the resistance element RE to a ground terminal Vss according to the voltage of a word line WL.

FIG. 21 is a circuit diagram illustrating yet another embodiment of the memory cell MC of FIG. 2.

Comparing with the memory cell MC that has been described above with reference to FIG. 3, a selection element is not provided to a memory cell MC. A resistance element RE is connected between a word line WL and a bit line BL. Exemplarily, based on differences between the potential of non-selection word lines, the potential of a selection word line, the potential of non-selection bit lines and the potential of a selection bit line, a memory cell MC is selected. For example, a memory cell MC is selected based on an equipotential method.

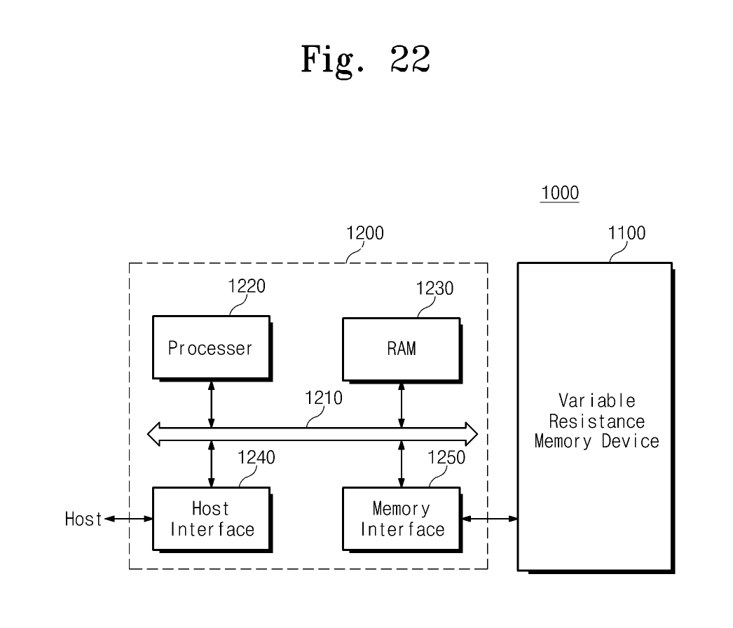

FIG. 22 is a block diagram of a memory system 1000 capable of incorporating a variable resistance memory device, like the one described in relation to FIGS. 1, 12 and 17 according to an embodiment of the inventive concept.

Referring to FIG. 22, a memory system 1000 generally comprises a variable resistance memory device 1100 and a controller 1200.

The controller 1200 is connected to a host and the variable resistance memory device 1100. In response to a request from the host, the controller 1200 accesses the variable resistance memory device 1100. For example, the controller 1200 controls the read, writing, erasion and background operations of the variable resistance memory device 1100. The controller 1200 provides an interface between the variable resistance memory device 1100 and the host. The controller 1200 drives a firmware for controlling the variable resistance memory device 1100.

As described above with reference to FIG. 1, the controller 1200 provides a control signal CTRL and an address ADDR to the variable resistance memory device 1100. Furthermore, the controller 1200 exchanges data DATA with the variable resistance memory device 1100.

The controller 1200 may further include elements such as a system bus 1210, a processor 1220, a RAM 1230, a host interface 1240 and a memory interface 1250.

The system bus 1210 provides a channel between the elements of the controller 1200. The processor 1220 controls the overall operation of the controller 1200. The RAM 1230 is used as at least one of the working memory of the processor 1200, a cache memory between the variable resistance memory device 1100 and the host, and a buffer memory between the variable resistance memory device 1100 and the host.

The host interface 1240 includes a protocol for performing data exchange between the host and the controller 1200. The controller 1200 may communicate with an external device (e.g., a host) through at least one of various conventionally understood interface protocols such as a Universal Serial Bus (USB) protocol, a Multimedia Card (MMC) protocol, a Peripheral Component Interconnection (PCI) protocol, a PIC-Express (PCI-E) protocol, an Advanced Technology Attachment (ATA) protocol, a Serial-ATA protocol, a Parallel-ATA protocol, a Small Component Small Interface (SCSI) protocol, an Enhanced Small Disk Interface (ESDI) protocol and an Integrated Drive Electronics (IDE) protocol. A memory interface interfaces with the variable resistance memory device 1100.

The memory system 1000 may additionally include an error correction block. The error correction block detects and corrects the error of data that is read from the variable resistance memory device 1100 with an Error Correction Code (ECC). Exemplarily, the error correction block is provided as the element of the controller 1200. The error correction block may be provided as the element of the variable resistance memory device 1100.

The controller 1200 and the variable resistance memory device 1100 may be integrated in one semiconductor device. Exemplarily, the controller 300 and the variable resistance memory device 1100 may be integrated in one semiconductor device and thereby configure a memory card. For example, the controller 1200 and the variable resistance memory device 1100 may be integrated in one semiconductor device and thereby configure a memory card such as a PC card (Personal Computer Memory Card International Association (PCMCIA)), a Smart Media Card (SMC), a memory stick, a Multimedia Card (MMC) (RS-MMC, and MMCmicro), an SD card (miniSD, microSD, and SDHC).

The controller 1200 and the variable resistance memory device 1100 are integrated in one semiconductor device and thereby configure a Solid State Drive (SSD). The SSD includes a storage device that stores data in a semiconductor memory. When the memory system 1000 is used as the SSD, the operation speed of the host connected to the memory system 100 is considerably improved.

As another example, the memory system 1000 is provided as any one of the various elements of an electronic device such as a computer, an Ultra Mobile PC (UMPC), a workstation, a net-book, a Personal Digital Assistant (PDA), a portable computer, a web tablet, a wireless phone, a mobile phone, a smart phone, an e-book, a Portable Multimedia Player (PMP), a portable game machine, a navigation device, a black box, a digital camera, a Digital Multimedia Broadcasting (DMB) player, a digital audio recorder, a digital audio player, a digital picture recorder, a digital picture player, a digital video recorder, a digital video player, a device that may transmit/receive information in a wireless environment, any one of various electronic devices configuring a home network, any one of various electronic devices configuring a computer network, any one of various electronic devices configuring a telematics network, RFID devices, or any one of any one of various elements configuring a computing system.

The variable resistance memory device 1100 or the memory system 1000 may be mounted as various types of packages. For example, the variable resistance memory device 1100 or the memory system 1000 may be packaged in a package type such as Package on Package (PoP), Ball Grid Arrays (BGAs), Chip Scale Packages (CSPs), Plastic Leaded Chip Carrier (PLCC), Plastic Dual In-Line Package (PDIP), Die In Waffle Pack (DIWP), Die In Wafer Form (DIWF), Chip On Board (COB), Ceramic Dual In-Line Package (CERDIP), Plastic Metric Quad Flat Pack (MQFP), Thin Quad Flat Pack (TQFP), Small Outline Package (SOP), Shrink Small Outline Package (SSOP), Thin Small Outline Package (TSOP), Thin Quad Flat Pack (TQFP), System In Package (SIP), Multi Chip Package (MCP), Wafer Level Stack Package (WLSP), Die In Wafer Form (DIWF), Die On Waffle Package (DOWP), Wafer-level Fabricated Package (WFP) and Wafer-Level Processed Stack Package (WSP), thereby being mounted.

The RAM 1230 of the controller 1200 may include at least one variable resistance memory device such as the one described above in relation to FIGS. 1, 12 and 17. That is, the RAM 1230 of the controller 1200 may include a variable resistance memory.

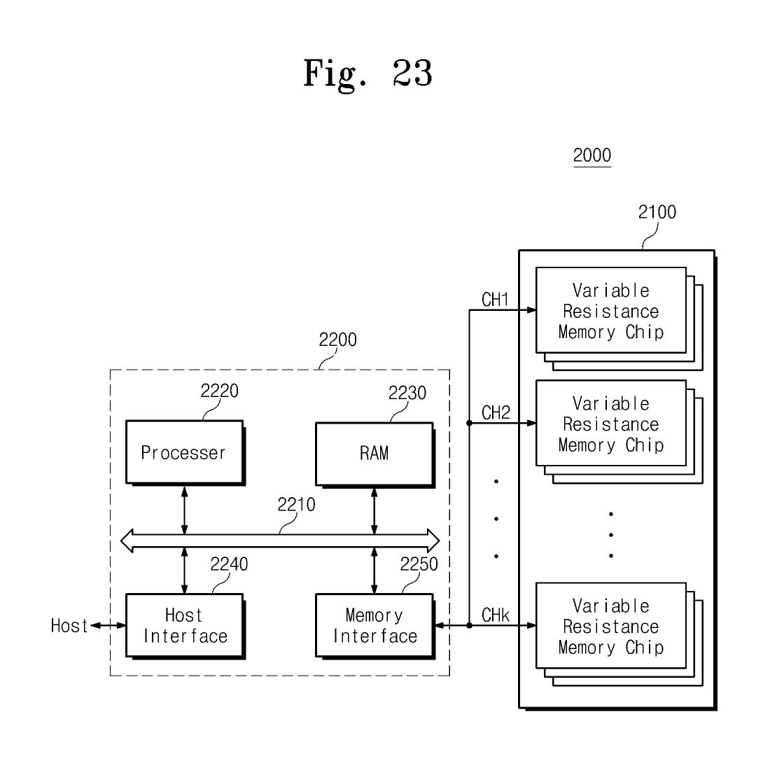

FIG. 23 is a block diagram illustrating one possible application example 2000 for the memory system 1000 of FIG. 21.

Referring to FIG. 23, a memory system according to an embodiment of the inventive concept generally comprises a variable resistance memory device 2100 and a controller 2200. The variable resistance memory device 2100 includes a plurality of variable resistance memory chips. The plurality of variable resistance memory chips are divided into a plurality of groups. The respective groups of the plurality of variable resistance memory chips communicate with the controller 2200 through one common channel. In FIG. 23, the plurality of variable resistance memory chips is illustrated to communicate with the controller 2200 through first to kth channels CH1 to CHk. Each of the variable resistance memory chips is configured identically to any one of the variable resistance memory devices 100, 200 and 300 that have been respectively described above with reference to FIGS. 1, 12 and 17.

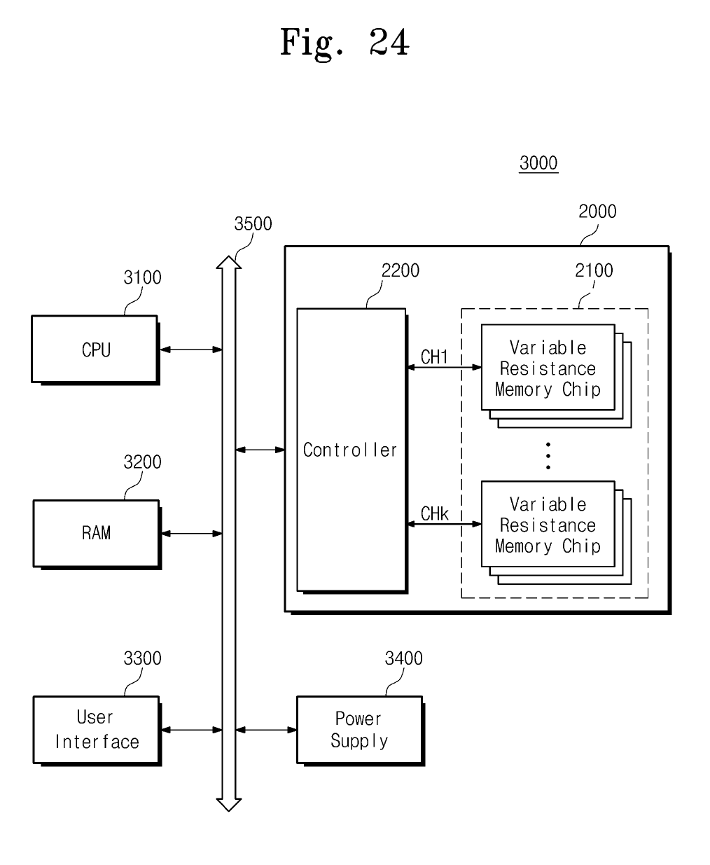

FIG. 24 is a block diagram of a computational system 3000 comprising the memory system 2000 which has been described above with reference to FIG. 23.

Referring to FIG. 24, the computational system 3000 according to an embodiment of the inventive concept comprises a Central Processing Unit (CPU) 3100, a RAM 3200, a user interface 3300, a power supply 3400, and a memory system 2000.

The memory system 2000 is electrically connected to the CPU 3100, the RAM 3200, the user interface 3300 and the power supply 3400 through the system bus 3500. Data, which is provided through the user interface 3300 or is processed by the CPU 3100, is stored in the memory system 2000. The memory system 2000 includes the controller 2200 and the variable resistance memory device 2100.

In FIG. 24, the variable resistance memory device 2100 is illustrated to be connected to the system bus 3500 through the controller 2200. However, the variable resistance memory device 2100 may be directly connected to the system bus 3500. At this point, the functions of the controllers 1200 and 2200 that have been respectively described above with reference to FIGS. 22 and 23 are performed by the CPU 3100.

In FIG. 24, the memory system 2000 that has been described above with reference to FIG. 23 is illustrated to be provided. However, the memory system 2000 may be replaced by the memory system 1000 that has been described above with reference to FIG. 22.

The computational system 3000 may include all the memory systems 1000 and 2000 that have been respectively described above with reference to FIGS. 22 and 23.

According to embodiments of the inventive concept, writing is performed based on the set pulse having a narrower width than the reset pulse. Moreover, application of the set pulse is stopped to the passed memory cells. Accordingly, provided are the variable resistance memory having an enhanced operation speed, the operation method thereof and the memory system including the same.

The above-disclosed subject matter is to be considered illustrative and not restrictive, and the appended claims are intended to cover all such modifications, enhancements, and other embodiments, which fall within the scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. An operating method for a variable resistance memory device, the method comprising:
applying a reset pulse to a plurality of memory cells to be written in a reset state (reset memory cells), and applying a set pulse to a plurality of memory cells to be written in a set state (set memory cells),
wherein a duration of the set pulse is less than a duration of the reset pulse.

2. The operating method of claim 1, wherein the applying the set pulse comprises:
applying a first set pulse to the set memory cells;
performing a verification operation on the set memory cells following application of the first set pulse to generate verification results; and
applying a second set pulse to at least one of the set memory cells in response to the verification results.

3. The operating method of claim 2, wherein the second set pulse is equal in duration to the first set pulse.

4. The operating method of claim 2, wherein the second set pulse has a greater level than the level of the first set pulse.

5. The operating method of claim 2, wherein the at least one of the set memory cells has a reset state following application of the first set pulse as indicated by the verification results.

6. The operating method of claim 1, wherein the applying the set pulse to the set memory cells comprises iteratively applying a set pulse to the set memory cells through a number of set loops until all of the set memory cells are passed by exhibiting a normal set state resistance.

7. The operating method of claim 6, wherein the each set loop comprises performing a set operation using a set-loop defined set voltage, and then performing a verification operation on the set memory cells.

8. The operating method of claim 7, wherein each set-loop defined set voltage is incrementally increased with each successive set loop.

9. The operating method of claim 7, wherein each set-loop defined set voltage is incrementally decreased with each successive set loop.

10. The operating method of claim 6, wherein each successive set loop is performed during a time period less than or equal to an immediately preceding set loop.

11. A variable resistance memory device, comprising:
a memory cell array comprising a plurality of memory cells; and
a read and write (R/W) circuit, wherein the R/W circuit is configured to apply a reset pulse to a plurality of memory cells to be written in a reset state (reset memory cells), and apply a set pulse to a plurality of memory cells to be written in a set state (set memory cells), wherein a duration of the set pulse is less than a duration of the reset pulse.

12. The variable resistance memory device of claim 11, wherein the R/W circuit is further configured such that applying the set pulse comprises:
applying a first set pulse to the set memory cells;
performing a verification operation on the set memory cells following application of the first set pulse to generate verification results; and
applying a second set pulse to at least one of the set memory cells in response to the verification results.

13. The variable resistance memory device of claim 12, wherein the second set pulse is equal in duration to the first set pulse.

14. The variable resistance memory device of claim 12, wherein the second set pulse has a greater level than the level of the first set pulse.

15. The variable resistance memory device of claim 12, wherein the at least one of the set memory cells has a reset state following application of the first set pulse as indicated by the verification results.

16. The variable resistance memory device of claim 11, wherein the R/W circuit is further configured such that applying the set pulse to the set memory cells comprises iteratively applying a set pulse to the set memory cells through a number of set loops until all of the set memory cells are passed by exhibiting a normal set state resistance.

17. The variable resistance memory device of claim 16, wherein the each set loop comprises performing a set operation using a set-loop defined set voltage, and then performing a verification operation on the set memory cells.

18. The variable resistance memory device of claim 17, wherein each set-loop defined set voltage is incrementally increased with each successive set loop.

19. The variable resistance memory device of claim 16, wherein each successive set loop is performed during a time period less than or equal to an immediately preceding set loop.

20. A memory system, comprising:
a variable resistance memory device; and
a controller controlling the variable resistance memory device, wherein the variable resistance memory device comprises:
a memory cell array comprising a plurality of memory cells; and
a read and write (R/W) circuit, wherein the R/W circuit is configured to apply a reset pulse to a plurality of memory cells to be written in a reset state (reset memory cells), and apply a set pulse to a plurality of memory cells to be written in a set state (set memory cells), wherein a duration of the set pulse is less than a duration of the reset pulse.
